(19) United States
(12) Patent Application Publication
(10) Pub. No.: US 2024/0043990 A1
(43) Pub. Date: Feb. 8, 2024

(54) METHOD FOR FORMING LAYER ON DIFFERENT-DENSITY PATTERN REGIONS

(71) Applicant: ASM IP Holding B.V., Almere (NL)

(72) Inventor: Yoshio Susa, Tama-shi (JP)

(21) Appl. No.: 18/227,485

(22) Filed: Jul. 28, 2023

Related U.S. Application Data
(60) Provisional application No. 63/394,357, filed on Aug. 2, 2022.

(51) Int. Cl. C23C 16/04; C23C 16/50; C23C 16/56; C23C 16/26; C23C 16/32; C23C 16/40; C23C 16/34; C23C 16/36

(52) U.S. Cl. CPC C23C 16/045; C23C 16/50; C23C 16/56; C23C 16/26; C23C 16/325; C23C 16/401; C23C 16/345; C23C 16/36

(57) ABSTRACT

A method for forming a layer on a low-density pattern region having first recesses and a high-density pattern region having second recesses formed on a substrate to be processed, includes a first step of forming a first layer in the first recesses so as to be higher than the first recess top and forming a second layer in the second recesses so as to be higher than the second recess top, an etching step of etching a first layer so as to be higher than the first recess top and of etching a second layer so as to be lower than the second recess top, and a second step of forming a third layer on the first layer and of forming a fourth layer in the second recesses so as to be higher than the second recess top.

### CROSS-REFERENCE TO RELATED APPLICATIONS

This application claims priority to U.S. Provisional Patent Application Ser. No. 63/394,357 filed Aug. 2, 2022 titled METHOD FOR FORMING LAYER ON DIFFERENT-DENSITY PATTERN REGIONS, the disclosure of which is hereby incorporated by reference in its entirety.

### BACKGROUND OF THE INVENTION

### Field of the Invention

The present disclosure relates to a method for forming a layer on different-density pattern regions.

### Description of Related Art

The plasma CVD method is used as a method for forming a layer such as a carbon layer or a SiC layer on the surface of a substrate to be processed. For example, in US Patent Application Publication No. 2021/0151348, as a method of forming a carbon layer in recesses of a substrate to be processed provided with recesses, a first carbon layer is formed inside the recesses of the substrate to be processed, and after etching a part of the first carbon layer, a second carbon layer is formed inside the recesses.

As a substrate to be processed provided with a plurality of recesses, a substrate having a low-density pattern region in which the recesses are formed at a relatively low density and a high-density pattern region where recesses are formed at a relatively high density is known. When a layer is formed on the surface of such a substrate to be processed by the plasma CVD method, the layer may be formed relatively thick in the low-density pattern region because the recesses are filled with a small amount of the material, and the layer may be formed relatively thin in the high-density pattern region because the recesses are filled with a large amount of the materials.

### SUMMARY OF THE INVENTION

A first aspect of the present disclosure provides a method for forming a layer on a low-density pattern region where first recesses are formed at relatively low density and a high-density pattern region where second recesses are formed at relatively high density, in which the regions are formed on a surface of a substrate to be processed, the method including a first step in which, while supplying a material precursor gas and a carrier gas to the surface of the substrate to be processed on the side where the recesses are provided, and applying a high-frequency voltage to the gases to form plasma, a first layer is formed in the first recesses of the low-density pattern region so as to be higher than the top of the first recesses and a second layer is formed in the second recesses of the high-density pattern region so as to be higher than the top of the second recesses, an etching step in which, while supplying an etching gas and a carrier gas to the first layer and the second layer of the substrate to be processed, and applying a high-frequency voltage to the gases to form plasma, a first layer is etched so as to be higher than the top of the first recesses and a second layer is etched so as to be lower than the top of the second recesses, and a second step in which, while supplying a material precursor and a carrier gas to the surface of the substrate to be processed on the side where the recesses are provided, and applying a high-frequency voltage to the gases to form plasma, a third layer is formed on the first layer formed on the low-density pattern region and a fourth layer is formed in the second recesses of the high-density pattern region so as to be higher than the top of the second recesses.

### BRIEF DESCRIPTION OF THE DRAWINGS

FIG. 1 is a cross-sectional view of a substrate to be processed that can be used in a method for forming a layer according to an embodiment of the present disclosure.

FIG. 2 is a cross-sectional view of a film forming apparatus that can be used in a method for forming a layer according to an embodiment of the present disclosure.

FIG. 3 is a flow diagram of a method for forming a layer according to an embodiment of the present disclosure.

FIG. 4 is a cross-sectional view of the substrate to be processed after the first step in a method for forming a layer according to an embodiment of the present disclosure, (a) is a cross-sectional view of the low-density pattern region, and 4(b) is a cross-sectional view of the high-density pattern region.

FIG. 5 is a cross-sectional view of the substrate to be processed during the etching step in a method for forming a layer according to an embodiment of the present disclosure, (a) is a cross-sectional view of the low-density pattern region, and (b) is a cross-sectional view of the high-density pattern region.

FIG. 6 is a cross-sectional view of the substrate to be processed after the etching step in a method for forming a layer according to an embodiment of the present disclosure, 6(a) is a cross-sectional view of the low-density pattern region, and (b) is a cross-sectional view of the high-density pattern region.

FIG. 7 is a cross-sectional view of the substrate to be processed after the second step in a method for forming a layer according to an embodiment of the present disclosure, FIG. 7(a) is a cross-sectional view of the low-density pattern region, and FIG. 7(b) is a cross-sectional view of the high-density pattern region.

### DETAILED DESCRIPTION OF THE INVENTION

Hereinafter, the present disclosure will be described in detail with reference to the drawings as appropriate. The drawings used in the following description may be enlarged for convenience in order to make the features of the present disclosure easy to understand, and the dimensional ratio of each component may differ from the actual one. The materials, dimensions, etc. exemplified in the following description are examples, and the present disclosure is not limited thereto and it is possible to appropriately change and implement the present disclosure within a range in which the effects of the present disclosure can be obtained.

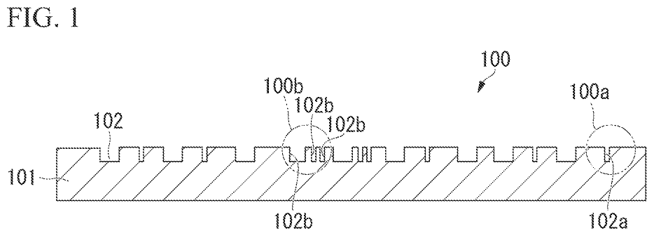

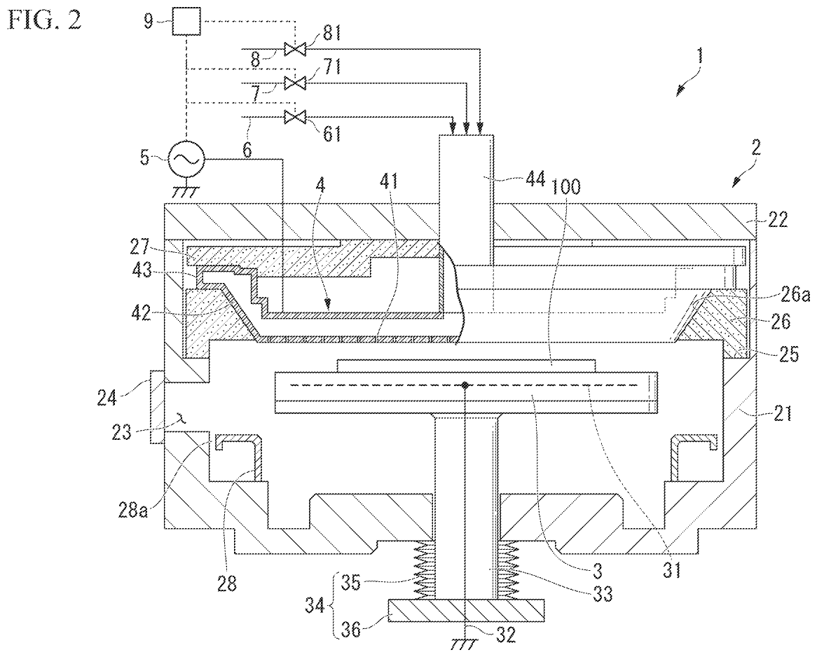

FIG. 1 is a cross-sectional view of a substrate to be processed that can be used in a method for forming a layer according to an embodiment of the present disclosure. FIG. 2 is a cross-sectional view of a film forming apparatus that can be used in the method for forming a layer according to an embodiment of the present disclosure.

The substrate 100 to be processed shown in FIG. 1 has a base substrate 101 and a plurality of recesses 102 provided on the surface of the base substrate 101. The substrate 100 to be processed has a low-density pattern region 100a and a high-density pattern region 100b. First recesses 102a of the low density pattern region 100a are provided at a relatively low density with respect to second recesses 102b of the high density pattern region 100b. The second recesses 102b of the high-density pattern region 100b are provided at a relatively high density with respect to the first recesses 102a of the low-density pattern region 100a. The area ratio of the first recesses 102a of the low density pattern region 100a is in the range of 10% or more and 70% or less. The area ratio of the second recesses 102b of the high-density pattern region 100b exceeds 70%. The area ratio is a ratio of the area of the opening of the recess 102 to the surface area of the substrate 100 to be processed in a plan view from the vertical direction of the substrate 100 to be processed.

The substrate 100 to be processed is, for example, a silicon substrate. The shape of the recess of the substrate 100 to be processed is not particularly limited, and for example, the shape of the opening of the recess may be circular or polygonal. The average aspect ratio of the plurality of recesses of the substrate 100 to be processed (average depth of recesses/average longest diameter of the openings of the recesses) may be, for example, in the range of 0.5 or more and 15 or less or in the range of 2 or more and 15 or less. Further, the average longest diameter of the opening of the recess may be, for example, in the range of 10 nm or more and 300 nm or less.

The layer formed on the substrate to be processed is, for example, a layer of at least one kind of inorganic substance selected from the group consisting of carbon, SiC, SiO, SiN, SiCN, SiCN and SiCOH (low-k). The thickness of the layer is, for example, in a range of 5 nm to 1000 nm.

The film forming apparatus 1 shown in FIG. 1 has a chamber 2. The chamber 2 includes a susceptor 3 arranged inside and a shower head 4 arranged above the susceptor 3. Further, the film forming apparatus 1 has a high frequency power supply 5, a material precursor gas pipe 6, a carrier gas pipe 7, an etching gas pipe 8, and a controller 9.

The chamber 2 is a substantially cylindrical body. The chamber 2 has a chamber body 21 and a lid member 22. The chamber body 21 and the lid member 22 may be made of a metal material. As the metal material, for example, aluminum can be used.

An entry/takeout port 23 for a substrate 100 to be processed is provided on the side of the chamber body 21. The entry/takeout port 23 can be opened and closed by a door portion 24. A recess 25 is provided on the inner wall surface of the chamber body 21 above the entry/takeout port 23. A shower head fixing member 26 is arranged in the recess 25. The shower head fixing member 26 is a ring-shaped member having an inverted conical opening 26a having the lower inner diameter smaller than the upper inner diameter. As the material of the shower head fixing member 26, for example, a ceramic material such as Al₂O₃ can be used. A high frequency shielding plate 27 is arranged between the shower head 4 and the lid member 22. As the material of the high frequency shielding plate 27, for example, a ceramic material such as Al₂O₃ can be used.

An exhaust gas pipe 28 is arranged at the bottom of the chamber main body 21. The exhaust gas pipe 28 has an exhaust gas port 28a provided along the inner wall surface of the chamber main body 21. The gas introduced into the chamber 2 is discharged to the outside from an exhaust gas port (not shown) through the exhaust gas pipe 28.

The susceptor 3 is circular in a plan view. The surface of the susceptor 3 on the shower head 4 side is a mounting surface on which the substrate 100 to be processed is mounted. The susceptor 3 has an electrode 31 inside. The electrode 31 is connected to the ground wiring 32. The shape of the electrode 31 is, for example, a plate shape, a wire mesh shape, or a punching metal shape. As the material of the electrode 31, for example, a refractory metal such as tungsten, tantalum, molybdenum, niobium, ruthenium, and hafnium can be used. Further, the susceptor 3 may be provided with a heater (not shown) for heating the substrate 100 to be processed inside. The temperature of the susceptor 3 is not limited in the present disclosure, but it is preferable that the temperature can be adjusted within the range of 300° C. or higher and 1000° C. or lower.

The susceptor 3 is provided with a susceptor support portion 33 in the center opposite to the shower head 4 side. The material of the susceptor 3 and the susceptor support 33 is, for example, a ceramic such as alumina or aluminum nitride. An elevating device 34 is arranged at the end of the susceptor support portion 33 opposite to the susceptor 3 side. The elevating device 34 has a movable portion 35 that can be expanded and contracted in the vertical direction, and a support portion 36 that supports the susceptor support portion 33 and the movable portion 35. When the movable portion 35 extends downward, the susceptor support portion 33 and the susceptor 3 move downward, and when the movable portion 35 contracts upward, the susceptor support portion 33 and the susceptor 3 move upward. By moving the susceptor 3 to the position of the entry/takeout port 23 of the chamber main body 21, the substrate 100 to be processed can be taken in and out.

The shower head 4 has a plurality of through gas holes 41 on the lower surface facing the susceptor 3. The material of the shower head 4 is, for example, stainless steel. The side surface 42 of the shower head 4 is in contact with the opening 26a of the shower head fixing member 26. The flange portion 43 of the shower head 4 is sandwiched between the shower head fixing member 26 and the high frequency shielding plate 27. A gas introduction pipe 44 is connected to the central portion of the shower head 4 opposite to the susceptor 3 side.

The high frequency power supply 5 is connected to the shower head 4. By turning on the high frequency power supply 5, a high frequency voltage is applied between the shower head 4 and the susceptor 3. The frequency of the AC voltage supplied from the high frequency power supply 5 is, for example, in the range of 13.56 MHz or more and 60 MHz or less.

A material precursor gas pipe 6, a carrier gas pipe 7 and an etching gas pipe 8 are connected to a gas introduction pipe 44 of a shower head 4.

The material precursor gas pipe 6 has a first valve 61 for adjusting the start and the stop of supply of the material precursor gas. The material precursor gas is a gas of a material for forming a layer by a CVD method. For example, when the layer is a carbon layer, a carbon precursor gas containing a compound represented by the following general formula (I) can be used as the material precursor gas:

CxHyOz (I)

(in the above general formula (I), x represents a number of 1 or more, y represents a number of 2 or more, and z represents 0 or a number of 1 or more.)

The compound represented by the general formula (I) may be a chain compound or a cyclic compound. The cyclic compound includes alicyclic compounds, aromatic compounds and heterocyclic compounds. Further, the compound represented by the general formula (I) may be a saturated compound or an unsaturated compound. Examples of the carbon precursor gas include methane (CH₄) gas, acetylene (C₂H₂) gas, propylene (C₃H₆) gas, cyclobutane (C₄H₈) gas, 1,3-dimethyladamantane (C₁₂H₂₀) gas, and bicyclo [2.2.1]hepta-2,5-diene (2,5-norbornadiene: C₂H₈) gas, adamantane (C₁₀H₁₆) gas, norbornene (C₂H₁₀) gas can be mentioned. These gases may be used alone or in combination of two or more.

The carrier gas pipe 7 has a second valve 71 that regulates the start and the stop of the carrier gas supply. As the carrier gas, for example, a rare gas can be used. The carrier gas is not limited in the present disclosure, but is preferably an argon gas or a helium gas.

The etching gas pipe 8 has a third valve 81 for adjusting the start and the stop of supply of the etching gas. The etching gas may be any gas that can etch the layer and does not corrode the chamber 2, the susceptor 3, and the shower head 4. As the etching gas, for example, hydrogen gas, oxygen gas, CF gas, CxHyFy gas (X is a number greater than or equal to 2, Y is a number greater than or equal to 2, and Z is a number greater than or equal to 2) or NO₂ gas can be used. Examples of the CF gas include CF₄ and C₄F₈. Examples of the CxHyFz include C₂H₂F₂.

The controller 9 is connected to the high frequency power supply 5 and controls the ON/OFF of the high frequency power supply 5. Further, the controller 9 is connected to the first valve 61 and controls the start/stop of the supply of the material precursor gas flowing through the material precursor gas pipe 6. The controller 9 is connected to the second valve 71 and controls the start/stop of the supply of the carrier gas flowing through the carrier gas pipe 7. The controller 9 is connected to the third valve 81 and controls the start/stop of the supply of the etching gas flowing through the etching gas pipe 8.

Next, a method for forming a layer using the film forming apparatus 1 will be described.

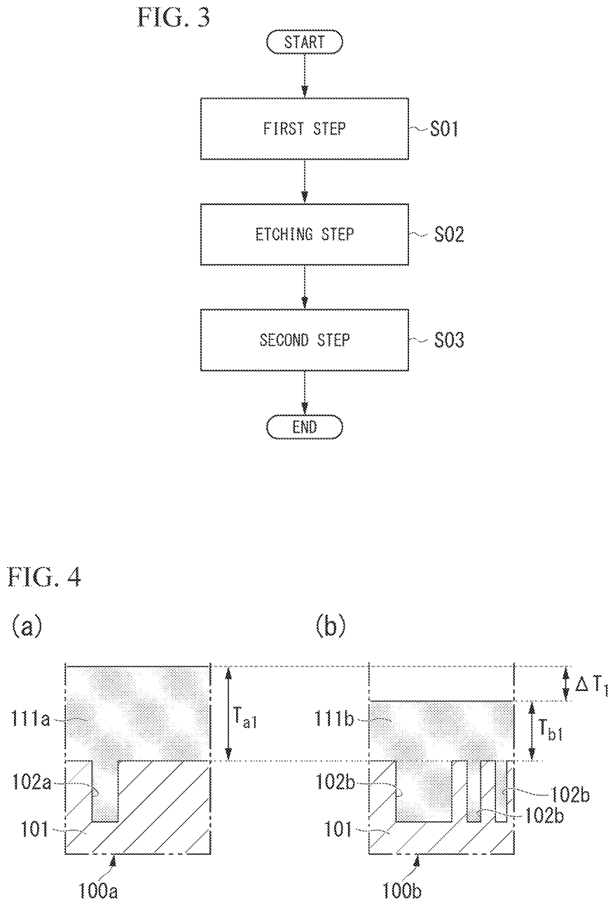

FIG. 3 is a flow diagram of the method for forming a layer according to an embodiment of the present disclosure.

As shown in FIG. 3, the method for forming a layer includes a first step S01, an etching step S02, and a second step S03.

FIG. 4 is a cross-sectional view of the substrate 100 to be processed after the first step S01. FIG. 4(a) is a cross-sectional view of the low-density pattern region 100a, and FIG. 4(b) is a cross-sectional view of the high-density pattern region 100b.

In the first process S01, the third valve 81 is closed, the first valve 61 and the second valve 71 are opened, the supply of the material precursor gas and the supply of the carrier gas are started, and the high-frequency power supply 5 is turned on. The material precursor gas and the carrier gas are supplied to the shower head 4 through a gas introduction pipe 44. The carrier gas supplied to the showerhead 4 is discharged toward the substrate 100 to be processed placed on the susceptor 3 through the through gas hole 41. A high-frequency voltage is applied between the showerhead 4 and the susceptor 3 by turning on the high-frequency power supply 5.

As described above, the plasma containing the material precursor gas and the carrier gas is formed on the surface of the substrate 100 on the side where the recesses 102 are provided, whereby the first layer 111a is formed in the low-density pattern region 100a and the second layer 111b is formed in the high-density pattern region 100b. The first layer 111a is formed higher than the top of the first recesses 102a of the low-density pattern region 100a, and the second layer 111b is formed higher than the top of the second recesses 102b of the high-density pattern region 100b. Since the second recesses 102b exist in the high-density pattern region 100b at a high density and the second recesses 102b are also filled with the second layer 111b, the formation rate of the second layer 111b is slower than the formation rate of the first layer 111a. Therefore, the difference ΔT₁ (Tₐ₁−T_{b1}) between the protruding height Tₐ₁ of the first layer 111a from the top of the first recesses 102a and the protruding height T_{b1} of the second layer 111b from the top of the second recess 102b becomes large. The difference ΔT₁ varies depending on the difference in volume between the first recesses 102a of the low-density pattern region 100a and the second recesses 102b of the high-density pattern region 100b, and is, for example, in a range of 10 nm to 100 nm. Although not limited in the present disclosure, the protruding height Tₐ₁ of the first layer 111a is, for example, in the range of 30 nm to 1000 nm, and the protruding height T_{b1} of the second layer 111b is, for example, in the range of 20 nm to 1000 nm.

The conditions for forming the layer in the first step 501 are not particularly limited. For example, the layer may be formed under a pressure of 100 Pa to 1500 Pa. The layer may be formed while heating the substrate 100 to be processed at a temperature of 40° C. or higher and 500° C. or lower. The frequency of the high-frequency voltage may be in a range from 13.56 MHz to 60 MHz.

In the etching step S02, the first valve 61 is closed, the second valve 71 and the third valve 81 are opened, the supply of the carrier gas and the supply of the etching gas are started, and the high-frequency power supply 5 is turned on. The carrier gas and the etching gas are supplied to a shower head 4 through a gas introduction pipe 44. The carrier gas supplied to the shower head 4 is discharged toward the substrate 100 to be processed placed on the susceptor 3 through the through gas hole 41. A high-frequency voltage is applied between the shower head 4 and the susceptor 3 by turning on the high-frequency power supply 5. Thereby, plasma containing the etching gas and the carrier gas is formed to etch the first layer 111a and the second layer 111b of the substrate 100 to be processed.

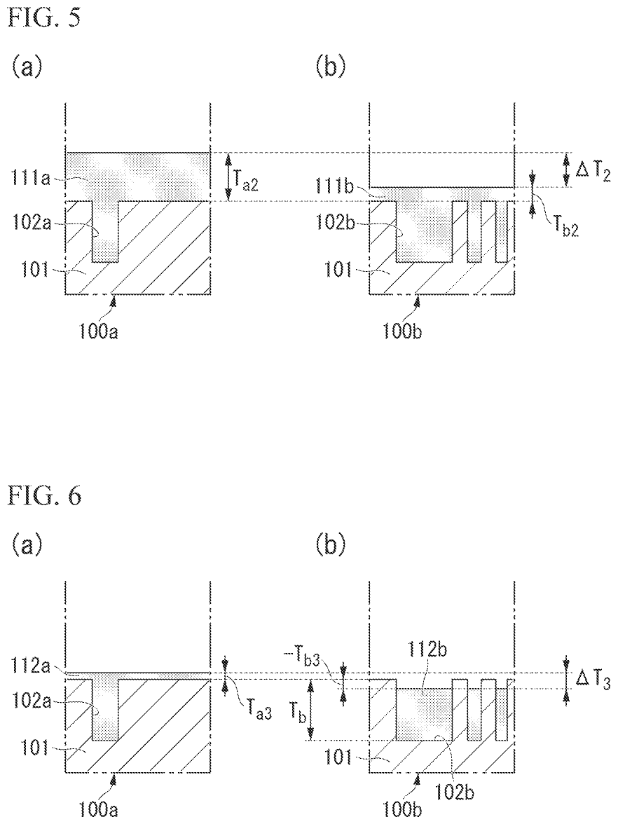

FIG. 5 is a cross-sectional view of the substrate 100 to be processed during the etching step S02, FIG. 5(a) is a cross-sectional view of the low-density pattern region 100a, and FIG. 5(b) is a cross-sectional view of the high-density pattern region 100b. By etching, the protruding height of the first layer 111a and the second layer 111b becomes low. Since the first layer 111a and the second layer 111b are formed of the same material, their etching rates are the same. Therefore, the difference ΔT₂ (Tₐ₂−T_{b2}) between the protruding height Tₐ₂ of the first layer 111a from the top of the first recess 102a and the protruding height T_{b2} of the second layer 111b from the top of the second recess 102b is maintained to be the same as the difference ΔT₁.

FIG. 6 is a cross-sectional view of the substrate 100 to be processed after the etching step S02, FIG. 6(a) is a cross-sectional view of the low-density pattern region 100a, and FIG. 6(b) is a cross-sectional view of the high-density pattern region 100b. When the second layer 111a is etched and the second layer 111a in the second recesses 102a is etched, the second recesses 102a has a narrow opening and the etching gas does not easily enter the second recesses, so that the etching rate of the second layer 111a rapidly decreases. Therefore, the difference ΔT₃ (Tₐ₃+T_{b3}) between the protruding height Tₐ₃ from the top of the first recess 102a of the first layer 112a after the etching step and the protruding height—T_{b3} from the top of the second recess 102b of the second layer 112b after the etching step is smaller than the difference ΔT₁. In the etching step S02, the first layer 111a is etched so that the height of the first layer 112a after the etching step is higher than the top of the first recesses 102a. The second layer 111b is etched so that the protruding height of the second layer 112b after the etching step is lower than the top of the second recesses 102b. Although not limited in the present disclosure, the protruding height Tₐ₃ of the first layer 112a after the etching step is, for example, in a range of 5 nm to 100 nm. The protruding height of the second layer 112b after the etching step—T_{b3} is, for example, in a range of −40 nm to −5 nm. The difference ΔT₃ is, for example, in a range of 10 nm to 95 nm.

The etching conditions in the etching step S02 are not particularly limited. For example, the etching may be performed while heating the substrate 100 to be processed at a temperature of 100° C. or higher and 500° C. or lower. The frequency of the high-frequency voltage may be in a range from 13.56 MHz to 60 MHz.

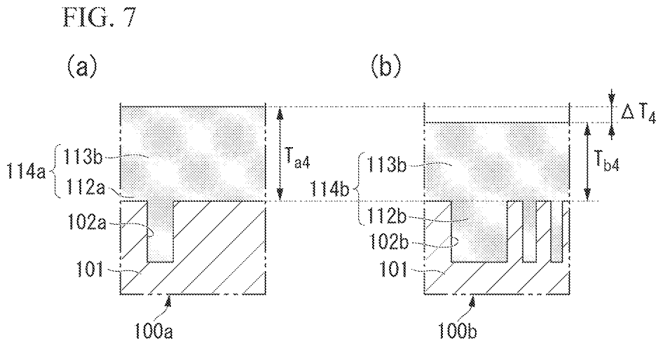

FIG. 7 is a cross-sectional view of the substrate 100 to be processed after the second step S03, FIG. 7(a) is a cross-sectional view of the low-density pattern region 100a, and FIG. 7(b) is a cross-sectional view of the high-density pattern region 100b.

In the second step S03, similarly to the first step S01, the third valve 81 is closed, the first valve 61 and the second valve 71 are opened, the supply of the carrier gas and the supply of the etching gas are started, and the high-frequency power supply 5 is turned on. Thus, the third layer 113a is formed in the low-density pattern region 100a, and the fourth layer 113b is formed in the high-density pattern region 100b. The third layer 113a is formed on the first layer 112a after the etching step. The fourth layer 113a is formed on the second recesses 102a so as to be higher than the top of the second recesses 102a. Thus, the layer 114a (the first layer 112a and the third layer 113a after the etching step) is formed in the low-density pattern region 100a, and the layer 114b (the second layer 112b and the fourth layer 113b after the etching step) is formed in the high-density pattern region 100b. Since the second layer 112b is filled in the second recesses 102b, the formation rate of the fourth layer 113b is faster than that of the second layer 111b, and the formation rate of the third layer 113a and the formation rate of the fourth layer 113b are almost the same. Therefore, the difference ΔT₄ (Tₐ₄−T_{b4}) between the protruding height Tₐ₄ from the top of the first recesses 102a of the covering layer 114a of the low-density pattern region 100a and the protruding height T_{b4} from the top of the second recesses 102b of the covering layer 114b of the high-density pattern region 100b is substantially the same as the difference ΔT₃. Therefore, the difference ΔT₄ is greatly reduced as compared with the difference ΔT₁ between the protruding height Tₐ₁ and the protruding height T_{b1} after the first step. Although not limited in the present disclosure, the difference ΔT₄ is, for example, in a range of 0 nm to 90 nm. The protruding height Tₐ₄ of the layer 114a of the low-density pattern region 100a is, for example, in the range of 20 nm to 1000 nm, and the protruding height T_{b4} of the layer 114b of the high-density pattern region 100b is, for example, in the range of 20 nm to 1000 nm.

The conditions for forming the layer in the second step S03 may be the same as the conditions for forming the layer in the first step S01.

The layer forming method the present embodiment can be industrially advantageously implemented by setting in advance the time of each step of the first step S01, the etching step S02, and the second step S03. Next, a method of setting the time of each step of the first step S01, the etching step S02, and the second step S03 will be described.

First, a layer is formed on a substrate to be processed for preliminary test. The forming conditions of the layer are the same as those of the first step S01. Next, the thickness of the layer formed on the substrate to be processed for preliminary test is measured. Here, the thickest portion of the layer may be a low-density pattern region, and the thinnest portion of the layer may be a high-density pattern region. Next, the time for forming the layer on the substrate to be processed for preliminary test by changing the time for forming the layer is defined as the time for forming the layer in the first step S01. For example, the layer forming time in the first step S01 may be a time when the protruding height of the layer in the low-density pattern region is in the range of 30 nm to 1000 nm and the protruding height of the layer in the high-density pattern region is in the range of 20 nm to 1000 nm.

Next, the etching is carried out using the substrate to be processed for preliminary test, on which the layer is formed in the time for forming the layer. The etching conditions are the same as those in the etching step S02. An etching time is defined as a forming time during which a layer having a desired thickness can be obtained by etching the substrate to be processed for preliminary test while changing the etching time. For example, the etching time may be a time when the protrusion height of the layer in the low-density pattern region after etching is within a range of 5 nm to 100 nm, the protrusion height of the layer in the high-density pattern region after etching is within a range of −40 nm to −5 nm, and the difference between the protrusion height of the layer in the low-density pattern region after etching and the protrusion height of the layer in the high-density pattern region after etching is within a range of 10 nm to 95 nm.

Next, a layer is formed using the substrate to be processed for preliminary test which was etched at the above etching time. The forming conditions of the layer are the same as those of the second step S03. The time for forming the layer on the substrate to be processed for preliminary test while changing the time for forming the layer is defined as the time for forming the layer in the second step S03. For example, the layer forming time in the second step S03 may be a time when the protruding height of the layer in the low-density pattern region is in the range of 20 nm to 1000 nm and the protruding height of the layer in the high-density pattern region is in the range of 20 nm to 1000 nm.

In the layer forming method of the present embodiment having the above-described structure, in the etching step S02, the first layer 111a is etched so that its height is higher than the top of the first recesses 102a, and the second layer 111b is etched so that its height is lower than the top of the second recesses 102b. As a result, the difference ΔT₄ between the protruding height Tₐ₄ of the layer 114a of the low-density pattern region 100a and the protruding height T_{b4} of the covering layer 114b of the high-density pattern region 100b becomes small. Therefore, according to the layer forming method of the present embodiment, the layers 114a and 114b having high thickness uniformity can be formed on the substrate 100 to be processed having the low-density pattern region 100a and the high-density pattern region 100b.

What is claimed is:

1. A method for forming a layer on a low-density pattern region where first recesses are formed at relatively low density and a high-density pattern region where second recesses are formed at relatively high density, in which the regions are formed on a surface of a substrate to be processed, the method comprising:
a first step in which, while supplying a material precursor gas and a carrier gas to the surface of the substrate to be processed on the side where the recesses are provided, and applying a high-frequency voltage to the gases to form plasma, a first layer is formed in the first recesses of the low-density pattern region so as to be higher than the top of the first recesses and a second layer is formed in the second recesses of the high-density pattern region so as to be higher than the top of the second recesses;
an etching step in which, while supplying an etching gas and a carrier gas to the first layer and the second layer of the substrate to be processed, and applying a high-frequency voltage to the gases to form plasma, a first layer is etched so as to be higher than the top of the first recesses and a second layer is etched so as to be lower than the top of the second recesses; and,
a second step in which, while supplying a material precursor and a carrier gas to the surface of the substrate to be processed on the side where the recesses are provided, and applying a high-frequency voltage to the gases to form plasma, a third layer is formed on the first layer formed on the low-density pattern region and a fourth layer is formed in the second recesses of the high-density pattern region so as to be higher than the top of the second recesses.

2. The method for forming a layer according to claim 1,
wherein the distance between the surface of the second layer filled in the second recesses of the high-density pattern region after the etching step and the top of the second recesses is in the range of 1/10 or more and 5/10 or less with respect to the depth of the second recesses.

3. The method for forming a layer according to claim 1,
wherein the etching gas is selected from the group consisting of hydrogen gas, oxygen gas, CF gas, CxHyFy (x represents a number of 2 or more, y represents a number of 2 or more, and z represents a number of 2 or more) gas and NO₂ gas.

4. The method for forming a layer according to claim 1, wherein the layer formed on the surface of the substrate to be processed is a carbon layer, the material precursor gas is a gas of a compound represented by the following general formula (I):
CxHyOz (I)
(in the above general formula (I), x represents a number of 1 or more, y represents a number of 2 or more, and z represents 0 or a number of 1 or more.)

5. The method for forming a layer according to claim 1,
wherein the first step and the second step are performed while heating the substrate to be processed at a temperature of 40° C. or higher and 500° C. or lower.

6. The method for forming a layer according to claim 1, wherein the etching step is performed while heating the substrate to be processed at a temperature of 100° C. or higher and 500° C. or lower.

7. The method for forming a layer according to claim 1, wherein the first step and the second step are performed under a pressure of 100 Pa or more and 1500 Pa or less.

8. The method for forming a layer according to claim 1, wherein the average aspect ratio of the plurality of recesses of the substrate to be processed is in the range of 0.5 or more and 15 or less, and the average longest diameter of the opening of the recess is in the range of 10 nm or more and 300 nm or less.

9. The method for forming a layer according to claim 1,
wherein the frequency of the high-frequency voltage in the first step, the etching step and the second step is in a range from 13.56 MHz to 60 MHz.

10. The method for forming a layer according to claim 1,
wherein the layer formed on the substrate to be processed is a layer of at least one kind of inorganic material selected from the group consisting of carbon, SiC, SiO, SiN, SiCN, SiCN and SiCOH (low-k).
